(19) United States
(12) Patent Application Publication
(10) Pub. No.: US 2026/0231750 A1
(43) Pub. Date: Aug. 6, 2026

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Po YU, Kaohsiung (TW); Wei Shun HUANG, Tainan (TW); Cheng-Yu LI, Tainan (TW); I-I CHENG, Tainan (TW); Li-Yi CHEN, Tainan (TW)

(21) Appl. No.: 19/043,728

(22) Filed: Feb. 3, 2025

(51) Int. Cl. H01L 23/522; H01L 21/768; H01L 23/528

(52) U.S. Cl. CPC H10W 20/42; H10W 20/082; H10W 20/088; H10W 20/089; H10W 20/435; H10W 20/056

(57) ABSTRACT

An interconnection structure over a device layer is provided. The interconnection structure comprises a first metal line in a dielectric layer and a first via self-aligned with the first metal line along a z-axis in the dielectric layer. The first via has a width W along an x-axis and a length L along a y-axis, where W/L ranges from about 1:3 to about 1:80.

### BACKGROUND

As the semiconductor industry introduces new generations of integrated circuits (IC) having higher performance and more functionality, the density of the elements forming the ICs increases, while the dimensions, sizes and spacing between components or elements are reduced. In the past, such reductions were limited only by the ability to define the structures photo-lithographically, device geometries having smaller dimensions created new limiting factors. With decreasing semiconductor device dimensions, improved semiconductor devices with improved sheet resistance, contact resistance, and capacitance are needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 and FIG. 2 are cross-sectional views of an interconnection structure formed in various stages of a fabrication process, and FIG. 3 is a top view of the interconnection structure in accordance with some embodiments.

FIG. 4 is a top view showing the dimensions of the vias of the interconnection structures as shown in FIGS. 1-3 in accordance with some embodiments.

FIG. 5 to FIG. 12 shows the processes for forming an interconnection structure with self-aligned vias in accordance with some embodiments.

FIG. 13 shows a cross-sectional view and a top view of an interconnection structure with self-aligned vias in accordance with some embodiments.

FIGS. 14 and 15 show different layouts of the self-aligned vias in multiple metallization layers of an interconnection structure in accordance with some embodiments.

FIG. 16 shows the cross-sectional views and top views of a self-aligned via and a via formed using traditional process in accordance with some embodiments.

FIG. 17 shows a via metal-oxide-metal (VIAMOM) in accordance with some embodiments.

FIG. 18 shows a cross-sectional of a self-aligned via in accordance with some embodiment.

FIG. 19 shows a method for forming an interconnection structure at the back-end-of-the-line (BEOL) stage in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As semiconductor technologies move into further advanced node, aggressive shrinkage of contact-to-gate pitch and interconnect structure formed in back-end-of-the-line (BEOL) is unavoidable. Shrunk dimensions of the BEOL interconnect structure results in reduced cross-sectional area of the conductive features, and thus increases the contact resistance Rc of the interconnect structure and drives up the resistance-capacitance product (RC) of the interconnect system and causes signal delay. The performance benefits gained at the front-end-of-the-line (FEOL) may easily be undone if the BEOL interconnect structure is inappropriately designed. The inappropriately designed BEOL interconnect structure may also impact performance of analog and radio-frequency (RF) device applications. The BEOL interconnect structure involves creation of stacked layers of metal wires that electrically interconnect the devices formed in FEOL process. The BEOL interconnect structure may easily include 12 to 15 levels of Cu wires. The Cu wiring schemes become more complex as more devices are formed in the semiconductor chip and connected with tighter pitch.

One way to resolve the RC delay issue is to reduce the contact resistance Rc (or sheet resistance Rs) by widening lithography window in the BEOL process. According to some embodiments, a semiconductor device with a BEOL interconnection structure formed in the BEOL process is provided. The BEOL interconnection structure provides wiring schemes to distribute clock and other signals, and provides power supply and ground connection, and transfers electrical signals between devices. The BEOL interconnection structure may be formed over a device layer in which devices such as transistors, diodes, imaging sensors, resistors, capacitors, inductors, memory cells, combinations thereof, and/or other suitable devices, may have been formed. In some embodiments, the transistors formed in the device layer may include nanostructure transistors having a plurality of channels wrapped around by the gate electrode layer. The term nanostructure is used herein to designate any material portion with nanoscale, or even microscale dimensions, and has an elongate shape, regardless of the cross-sectional shape of this portion. Thus, this term nanostructure designates both circular and substantially circular cross-section elongate material portions, and beam or bar-shaped material portions including for example a cylindrical in shape or substantially rectangular cross-section. The channel(s) of the semiconductor device structure may be surrounded by the gate electrode layer. The nanostructure transistors may be referred to as nanosheet transistors, nanowire transistors, gate-all-around (GAA) transistors, multi-bridge channel (MBC) transistors, or any transistors having the gate electrode layer surrounding the channels. In some embodiments, the device layer includes devices such as planar FET, FinFET, complementary FET (CFET), forksheet FET, or other suitable devices.

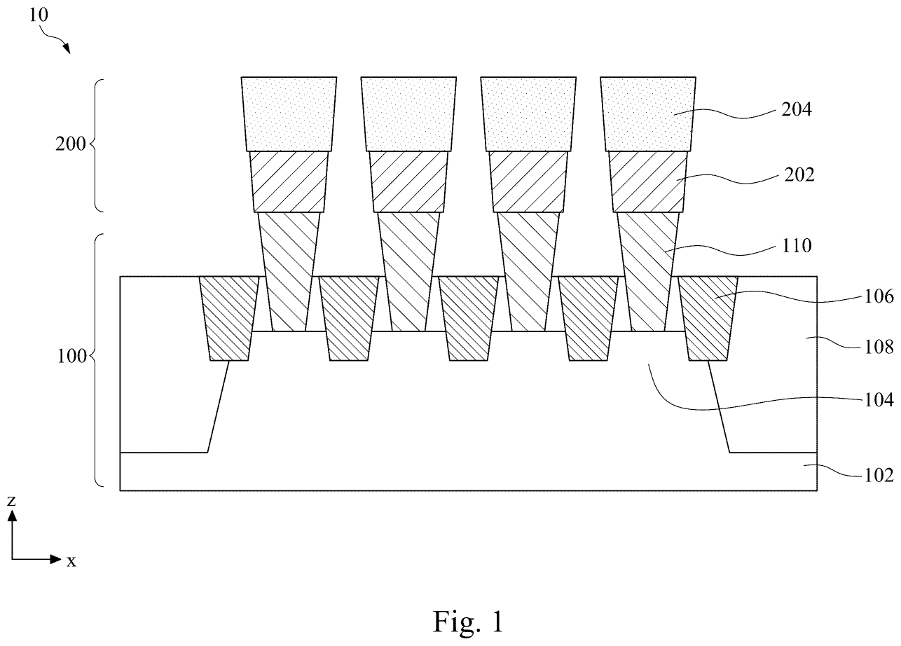

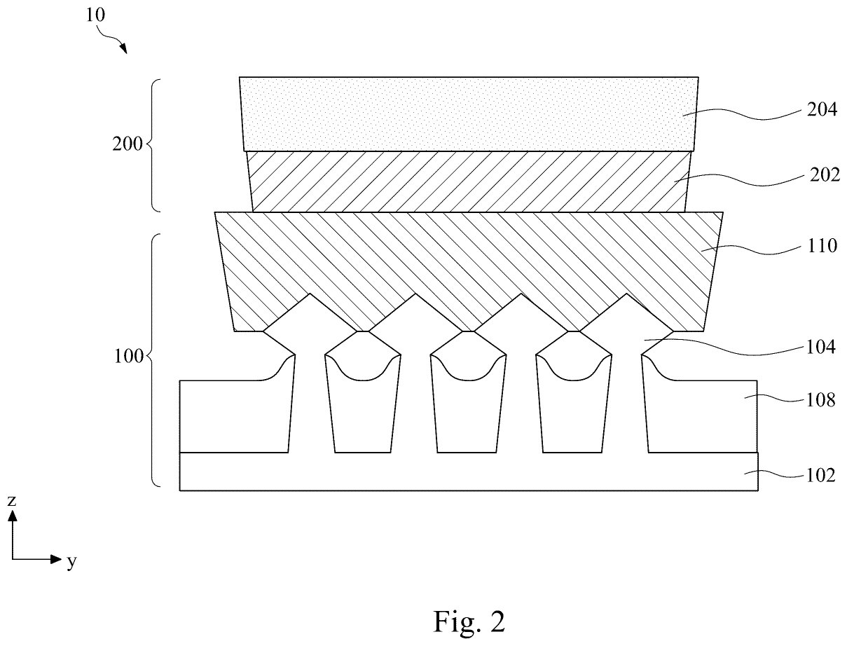

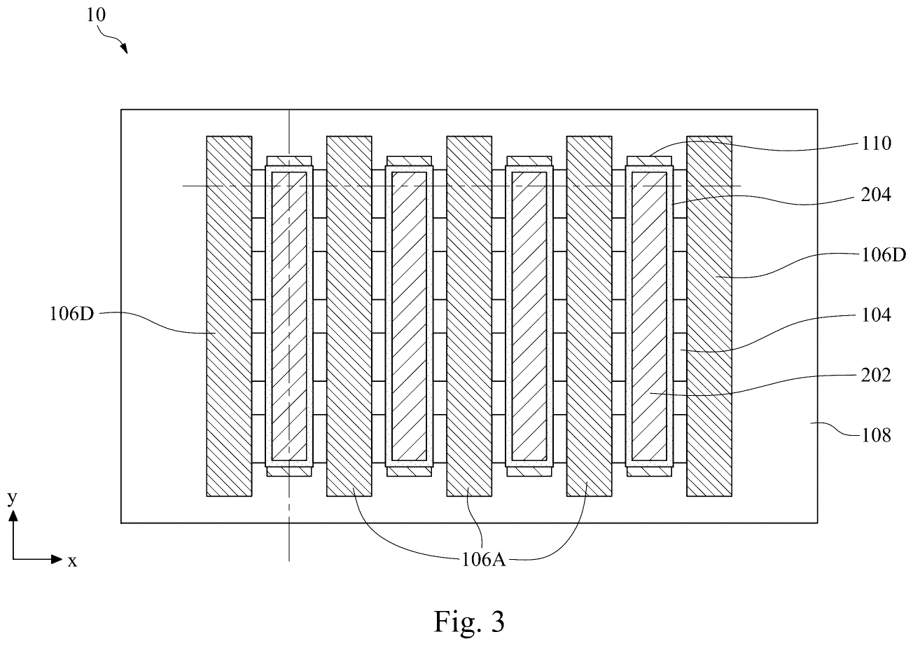

FIG. 1 shows a cross-sectional view of a semiconductor device 10 along an x-z plane, FIG. 2 shows a cross-sectional view of the semiconductor device 10 along an y-z plane, and FIG. 3 is a top view showing the semiconductor device 10 along the x-y plane. The semiconductor device 10 includes a device layer 100 in which an active region 104, for example, a source/drain region, is formed over a substrate 102. One metal gate 106 is formed between each pair of adjacent S/D regions 104 along the x-axis as shown in FIG. 1. The S/D regions 104 may include a semiconductor material such as Si or Ge, a III-V compound semiconductor, an II-VI compound semiconductor, or other suitable semiconductor material. Exemplary S/D region 104 may include, but are not limited to, Ge, SiGe, GaAs, AlGaAs, GaAsP, SiP, InAs, AlAs, InP, GaN, InGaAs, InAlAs, GaSb, AlP, GaP, and the like. The S/D regions 104 may include p-type dopants, such as boron; n-type dopants, such as phosphorus or arsenic; and/or other suitable dopants including combinations thereof. The S/D region 104 may be formed by an epitaxial growth method using CVD, atomic layer deposition (ALD) or molecular beam epitaxy (MBE). Channel regions may be formed from the same materials of the substrate 102, including Si, Ge, GeSn, SiGe, GaAs, InSb, GaP, GaSb, InAlAs, InGaAs, GaSbP, GaAsSb, GaN, GaP, or InP according to some embodiments. In some embodiments, the semiconductor devices are FinFETs with channel regions in the form of a plurality of fins each having at least three surfaces wrapped around by the metal gate 106. In some other embodiments, the devices are nanosheet transistors, and the channel regions may include two or more nanosheets surrounded by the metal gate.

In addition to the S/D region 104 and the metal gate 106, the device layer 100 may also include other devices and/or structures such as various types of transistors, diodes, imaging sensors, resistors, capacitors, inductors, memory cells, combinations thereof. In the embodiment as shown in FIGS. 1 and 3, the semiconductor device 10 includes three active metal gates 106A and two dummy gates 106D at two opposite sides of the active metal gates 106A. A field oxide layer (FOX) 108 may be formed between two neighboring transistors to isolate the metal gate 106 from the neighboring S/D regions 104. Conductive features 110 may be formed to interconnect with the S/D regions 104. In some embodiments, the conductive features 110 may be connected to two or more of the S/D regions 104. Thus, the conductive feature 110 may have a length, along the y-axis, across two or more fin structures. For example, as shown in FIGS. 2 and 3, the conductive feature may extend across over four S/D regions 104 and three fin structures The conductive features 110 may include one or more electrically conductive material such as W, Ru, Mo, Co, Ni, Ta, Cu, Al, TiN, and TaN. After the device layer 100 is formed, the process enters into the BEOL stage in which the metallization layers are formed. The metallization layers may include a number of metal-line layers and a number of via layers alternately stacked over each other. Each of the metal-line layers may include a number of metal lines extending through an upper portion of the dielectric layer, while each of the via layers may include a number of vias extending through a lower portion of the dielectric layer. In some embodiments, the metal-line layer may include the metal lines extending through a first dielectric layer, and the via layer may include the vias extending through a second dielectric layer. The first dielectric layer may be made of the same material or different material of the second dielectric layer. Some of the metal lines may be designed to directly connect with other metal lines in the same metal-line layer only, while some other metal lines may be designed to connect with both the metal lines in the same metal-line layer and vias formed in the one or both the immediately adjacent via layer(s). Some of the metal lines and the vias may also be dummy conductive features that are not intended to connect with other conductive features.

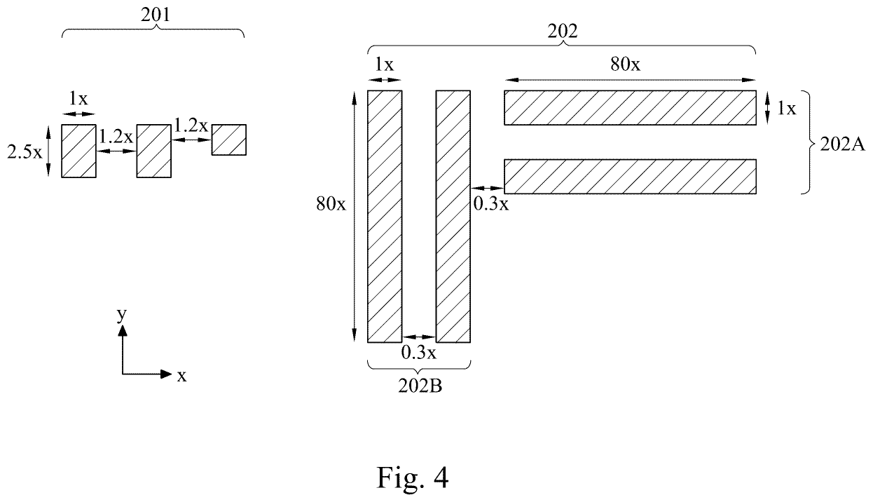

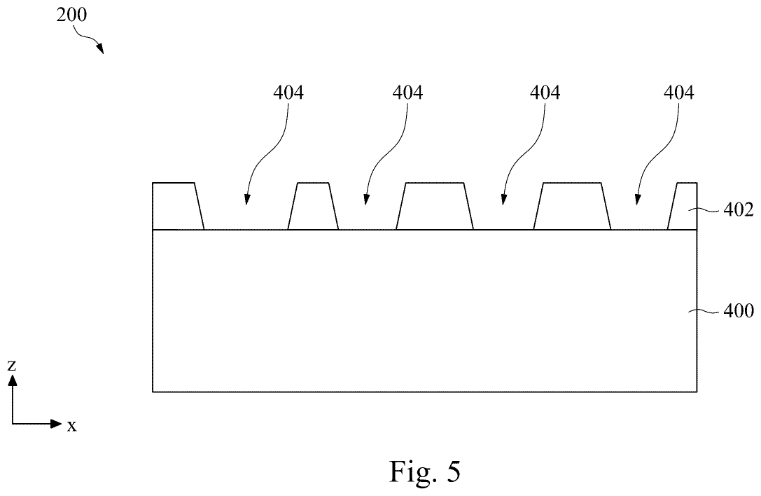

The BEOL stage may start with forming a dielectric layer (not shown) and conductive features 202 that extend vertically through the dielectric layer to interconnect the underlying conductive features 110 with the conductive features 204 formed subsequently and extend horizontally, for example, along the x-y plane above the conductive features 202. The vertically extending conductive features 202 may include the vias as discussed above. As shown in FIGS. 1 to 3, the vias 202 has a substantially square cross section on the x-z plane and an elongate rectangular cross section on the y-z plane. In addition to the vias 202, vias with other dimensions may also be formed in the BEOL stage (see FIGS. 5-12). For example, some vias may have a square cross-section along both the x-z plane and the x-y plane. The substantially square vias 201 may have a width W to length L ratio, that is, the ratio of the length W along x-axis to the length L along the y-axis, of about 1:2.5 with a via spacing of about 1.2 times of the width W. In contrast, the vias 202 with an elongate side along the y-axis has a width W to length L ratio ranging from about 1:3 to about 1:80 and a via space along the x-axis or y-axis of about 0.3 of the width W. The extended length along the y-axis increases the surface area A (W×L) along the x-y plane. The W/L ratio can be improved by changing the thickness of the dielectric layer 102 or the material for forming the hard mask according to some embodiments. In some embodiments, some of the vias may have an elongate side extending along the x-axis instead of the y-axis. For example, as shown in FIG. 4, the BEOL interconnection structure may vias 202A with an elongate side extending along the y-axis, and some vias 202B with an elongate side extending the x-axis.

The increased surface area along the x-y plane reduces the contact resistance Rc or sheet resistance Rs for current flowing across the x-y plane along z-axis. As a result, the RC delay that may impede circuit performance and increase power consumption can be minimized. The elongate side of the vias 202 along the y-axis not only increases the surface area along the x-y plane, but also increases the y-z plane. As it will be further discussed later, the increased surface area of the vias 202 along the y-z plane allows the vias to capture more charges, and thus increase the capacitance of the metal-oxide-metal (MOM) capacitor comprising two adjacent vias 202 and the dielectric layer between the vias 202 along the x-axis. In addition, as the conductive feature 110 may extend across over multiple S/D regions, some of the vias 202 may also be formed to cross over more than one S/D regions 104 as shown in FIGS. 2 and 3.

FIGS. 5 to 12 are cross-sectional views of a BEOL interconnection structure 200 (see FIG. 2) formed at various BEOL fabrication processes according to some embodiments. The BEOL interconnection structure 20 may be formed on a device layer in which various active devices are formed, for example, the device layer 100 as shown in FIGS. 1-3. In FIG. 5, a dielectric layer 400 is formed. The dielectric layer 400 may be an inter-metal dielectric layer (IMD) or interlayer dielectric layer (ILD) having a low dielectric constant (k) value, for example, lower than about 2.0 or other suitable value. The dielectric layer 400 may include a single layer of dielectric material or multiple layers made of the same low-k dielectric material or different low-k dielectric materials. The dielectric layer 400 has a thickness sufficient for forming both a metal line and a via. The low-k dielectric materials may include a porous organosilicate thin film such as SiOCH, tetraethylorthosilicate (TEOS) oxide, un-doped silicate glass, doped silicon oxide such as borophosphosilicate glass (BPSG), fused silica glass (FSG), phosphosilicate glass (PSG), fluorine-doped silicon dioxide, carbon-doped silicon dioxide, porous silicon dioxide, porous carbon-doped silicon dioxide, silicon carbon nitride (SiCN), silicon oxycarbide (SiOCN), spin-on silicon based polymeric dielectrics, or combinations thereof. The dielectric layer 400 may be formed through any of a variety of techniques, for example, CVD, PVD, ALD, RPECVD, LSMCD, coating, spin-coating or another process that is adapted to form a thin film layer.

A hard mask layer 402 is formed on the dielectric layer 400. The hard mask layer 402 is patterned to form openings 404 as shown in FIG. 5. The openings 404 expose portions of the dielectric layer 400 to be removed for forming trenches in the subsequent processes. The trenches are then filled with conductive materials to form metal lines subsequently. The metal lines may extend horizontally along the x-y plane to provide connection at the same metallization layer. Some of the metal lines may be designated to interconnect vias formed in the adjacent metallization layers in the subsequent processes. For example, some of the openings 404 may define metal lines in a metal-line layer Mₙ to interconnect vias formed in via line in Vₙ₋₁ and/or Vₙ₊₁ formed in the subsequent processes. The hard mask layer 402 may be formed from silicon nitride through a process such as a CVD process, although other materials, such as oxides, oxynitrides, silicon carbide, combinations of these, or the like, and other processes, such as PECVD, LPCVD, or even silicon oxide formation followed by nitridation, may alternatively be utilized. A suitable photolithography process may then be performed to form the openings 404 that expose portions of the dielectric layer 400. A bottom anti-reflective coating (BARC) (not shown) may be formed before forming PR layer 406.

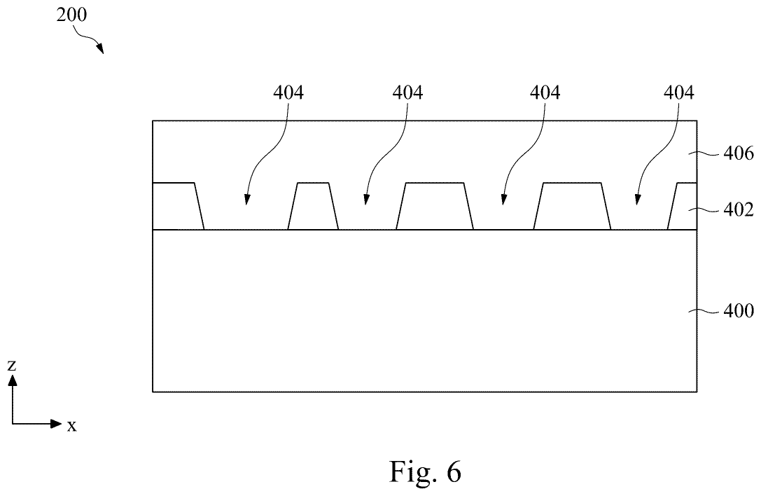

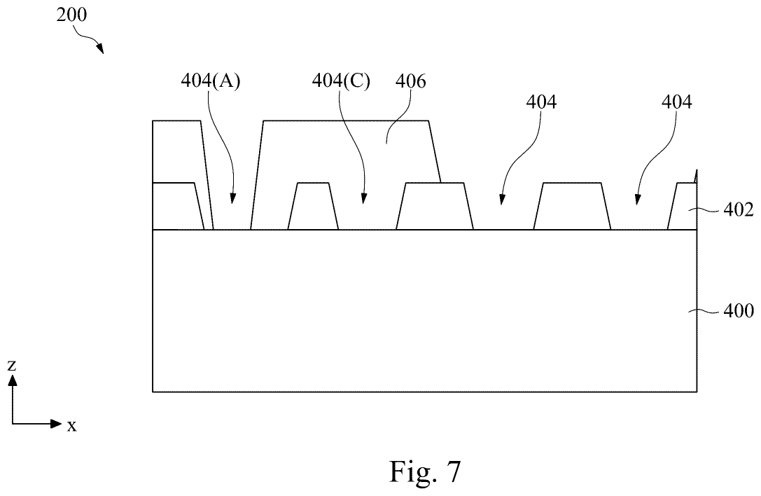

The openings 404 are then filled by a photoresist (PR) layer 406 formed over the hard mask layer 402 as shown in FIG. 6. In FIG. 7, the PR layer 406 is patterned to expose a predetermined number of openings 404 while some of the openings 404 (denoted as 404(C) in FIG. 7) remained covered and unexposed by the PR layer 406. The unexposed openings 404(C) may be designated to define the metal lines that provide horizontal connections with other metal lines formed at the same metallization layers, but not intended to provide direct connection vertically with conductive features formed at different metallization layers. According to some embodiments, a photolithography process may be performed on the PR layer 406 to result in some unexposed opening 404(C), some completely exposed openings 404, and some partially expose 404(A) as shown in FIG. 7. The portions of the hard mask 402 around the uncovered openings 404 are also exposed by the PR layer 406.

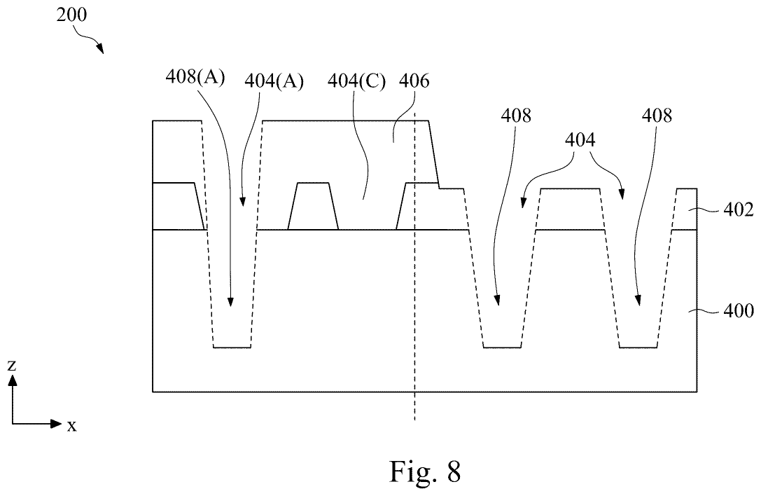

The portions of the dielectric layer 400 exposed within the partially covered openings 404(A) and uncovered openings 404 are removed with a predetermined depth to form openings, for example, via openings 408(A) and 408 as shown in FIG. 8. Removal of the portions of dielectric layer 400 in the partially covered openings 404(A) and the exposed openings 404 may be achieved by performing various types of etching processes. For example, dry etching processes such as plasma etching or reactive ion etching may be performed to form the vias openings 408(A) and 408. Depending on the materials used for forming the dielectric layer 400, etching conditions may need to be adjusted. For example, when the dielectric layer 400 contains TEOS, HF may be used as the etchant for the dry etching process. When the dielectric layer 400 includes layers of different dielectric materials, different etchants may be used at different depth of the dielectric layer.

As the via opening 408(A) is formed by extending the partially exposed opening 404(A), the linewidth, that is, the width W along the x-axis, of the via opening 408(A) is smaller than the linewidth of the via openings 408 under the openings 404. Further referring to FIG. 8, the portion of the hard mask layer 402 uncovered by the PR layer 406 may have a top surface slightly recessed from the top surface of the portion of the hard mask layer 402 covered by the PR layer 406 as the dry etching process performed to form the via openings 408 and 408(A) inevitably remove a negligible portion of the hard mask layer 402. To minimize the recess depth, the dry etching process is performed with a high etching selectivity of the dielectric layer to the hard mask. For example, when the hard mask layer 402 contains Si₃N₄ and the dielectric layer 400 contains SiO₂, a high selectivity of SiO₂ to Si₃N₄ is desired for performing the dry etching process.

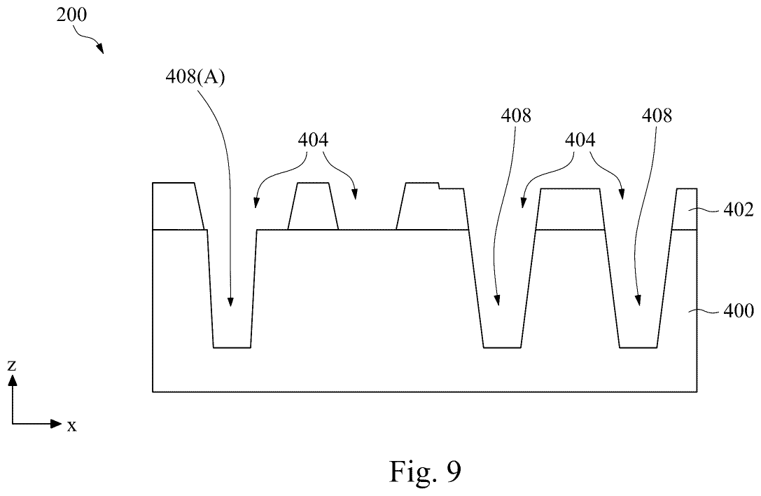

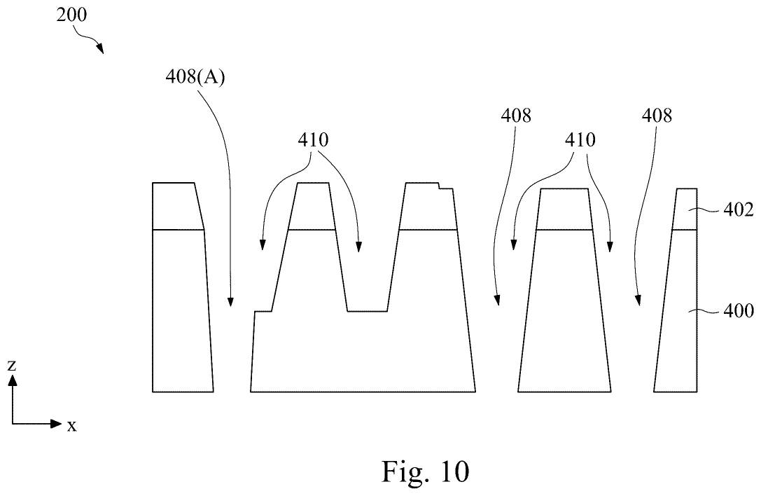

The PR layer 406 is then removed to expose the openings 404(C) that are previously covered and the partially covered openings 404(A). As shown in FIG. 9, via openings 408 and 408(A) with different linewidths are formed in the BEOL interconnection structure 200. After the PR layer 406 is removed, the portions of the dielectric layer 400 exposed within the openings 404 are removed with a predetermined depth to form trenches 410 in which metal lines that extend horizontally are to be formed subsequently. The exposed dielectric layer 400 may be removed by performing a dry etching process, for example, plasma etching or reactive ion etching process. At the same time, the remaining dielectric layer 400 within the via openings 408 and 408(A) may also be removed until the via openings 408 and 408(A) extend through the dielectric layer 410. For example, when the vias to be formed within the openings 408 and 408(A) are intended to interconnect with conductive features connected to the active regions formed in the underlying device layer, the dry etching process may be performed until the conductive features are exposed. As shown in FIG. 10, formation of the trenches 410 and the via openings 408 and 408(A) may be completed using the same dry etching process. In some embodiments, the trenches 410 may have been formed before the underlying conductive features or device layer is exposed, the trenches 410 may be widened with a linewidth larger than that of the opening 404 defined by the hard mask layer 402.

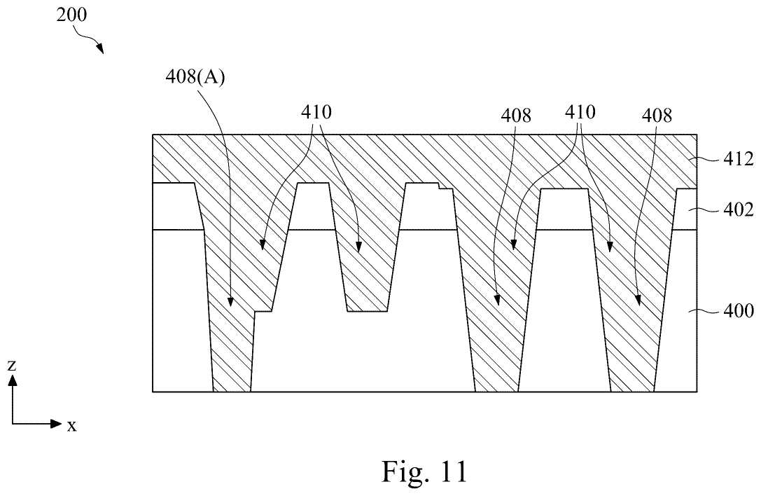

In FIG. 11, a metal layer 412 is formed over the hard mask layer 402 and fills the openings 404, the trenches 410, and the via openings 408 and 408A. Before the metal layer 412 is formed, a barrier layer (not shown) may be conformally formed on the sidewalls of the openings 404, the trenches 410, and the via openings 408 and 408A. The barrier layer may be deposited by CVD or PVD. The barrier layer may be used to prevent the metal layer 412 from diffusing into the dielectric layer 400. The barrier layer may also provide improved adhesion to the metal layer 412. The barrier layer may be made of a substantially aluminum free material such as Ta, TaN, TiN, or a composite layer made of Ta and TaN. In some embodiments, a thin seed layer is optionally formed on the barrier layer. The seed layer may include a metal alloy layer containing at least a main metal element, for example, copper (Cu) and an additive element such as manganese (Mn). In other embodiments, Ti, Nb, Cr, V, Y, Tc, Re, or other suitable material may be used as an additional for forming the seed layer. The seeding layer may be formed by PVD, CVD, PECVD, LPCVD, or other deposition techniques.

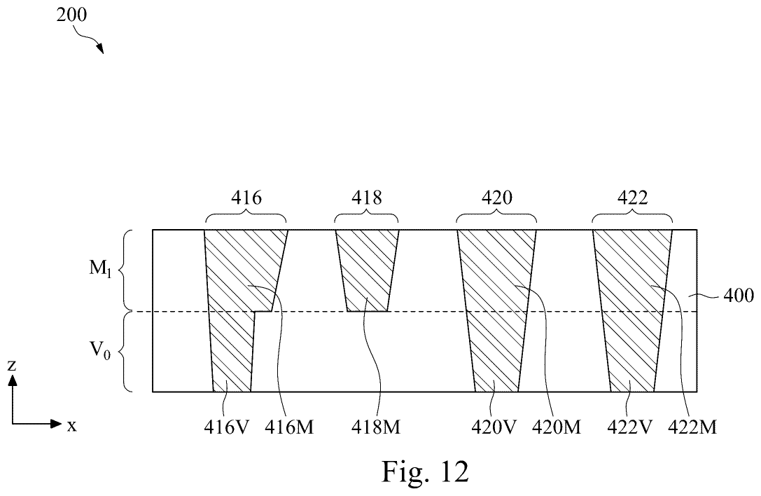

The material for forming the metal layer 412 may include Cu or Cu alloys. Other materials such as silver (Ag), gold (Au), tungsten (W), and the like may also be used for forming the metal layer 412. The metal layer 412 may be formed from an electrochemical copper deposition (ECD) process or other processes such as PVD and ALD and the likes. The ECD process may be adopted because of its high deposition and may result in larger grain size to ensure good electromigration. After formation of the metal layer 412, thermal treatment such as an annealing process may be performed. A chemical mechanical polishing (CMP) process is then performed until the hard mask layer 402 is removed, and a BEOL interconnection structure 200 including a via layer V₀ and a metal-line layer M₁ is formed as shown in FIG. 12.

In the embodiment as shown in FIG. 12, multiple conductive features, for example, the conductive features 416, 418, 420, and 422 are formed in the dielectric layer 400. The conductive feature 416 includes a metal line 416M at the metal-line layer M₁ and a via 416V at the underlying via layer V₀. The via 416V directly connects with the metal line 416M as shown in FIG. 12. The conductive feature 418 includes a metal line 418M at the metal-line layer M₁. The conductive feature 420 includes a metal line 420M at the metal-line layer M₁ and a via 420V at the via layer V₀. The via 420V is directly connected to the metal line 420M. The conductive feature 422 includes a metal line 422M at the metal-line layer M₁ and a via 422V at the via line V₀, where the via 422V is directly connected to the metal line 422M. According to one embodiment, the via line V₀ is formed over the device layer, and the vias 416V, 420V, 422V are connected to active regions such as S/D regions or other structures in the device layer.

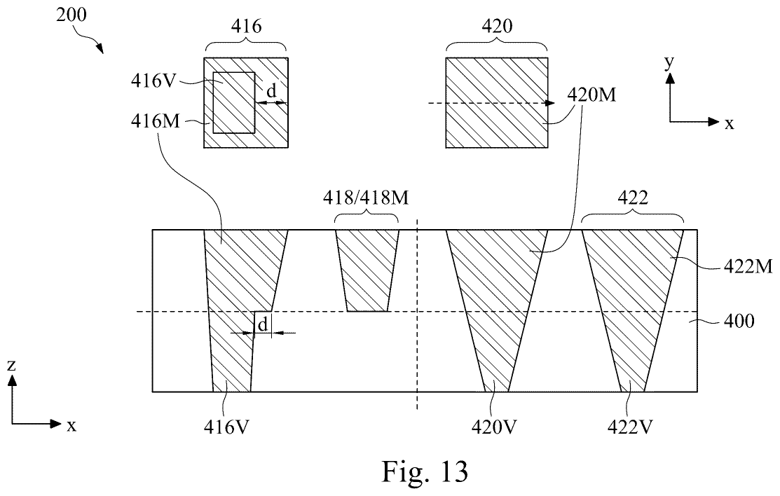

FIG. 13 provides the cross-sectional views of the BEOL interconnection structure 200 along the x-z plane and a top view of the conductive features 416 and 420 along the x-y plane. As shown in FIG. 13, one side of the conductive feature 416 has a discontinuous, for example, step-like, profile. The step may be as wide as about 0.02 μm, for example. The discontinuity of sidewall and the step width “d” may also be seen from the top views of the conductive features 416M and 416V provided in FIG. 13. Referring to FIGS. 5-12, the conductive feature 416 is formed through traditional dual damascene process as it is defined using both the mask layer 402 and the PR layer 406. In contrast, as the metal lines 420M and the vias 420V are formed using the same hard mask layer 402, the conductive feature 420 is formed with a substantially continuous sidewall. In other words, the via 420V is formed in a self-aligned manner and is thus referred to as the self-aligned via. The same applies to the via 422V of the conductive feature 422. In some embodiments, a small step may exist at the boundary of the metal line 420M and 422M and the via 420V and 422V of the conductive features 420 and 422, respectively. However, the width of the step may be limited within about 0.002 μm, which is ten times smaller than that of the conductive feature 416. In some other embodiment, a notch may exist at the boundary of the metal line 420M and the via 420V because the sidewall of the metal line 420 is further inclined during the process of extending the via opening 408 through the dielectric layer 400.

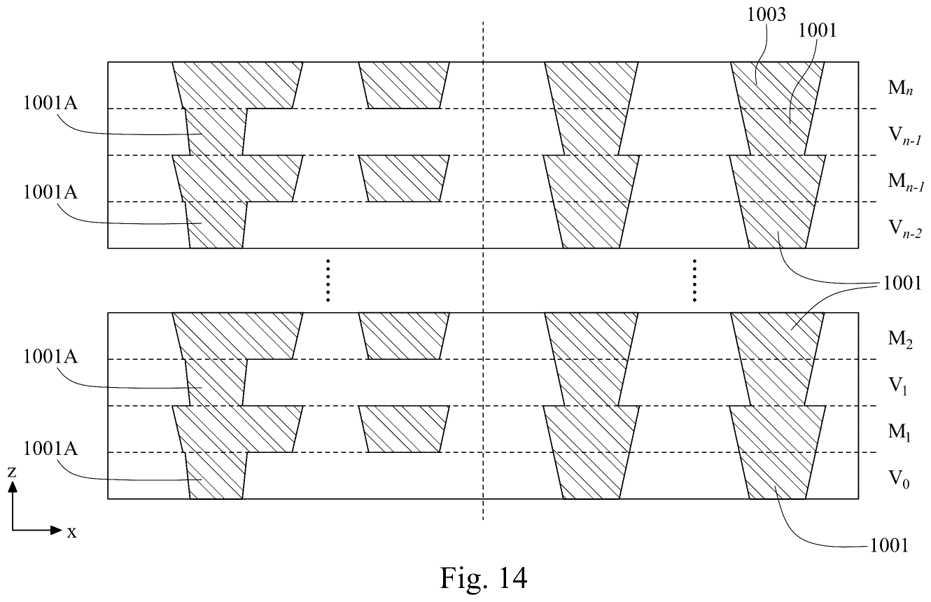

The processes as shown in FIGS. 5-12 may be repeated for forming different metallization layers. For example, the same process may be repeated for forming the upper metallization layers from via layer V₁, metal line layer M₂, to via layer Vₙ₋₁ and metal line layer Mₙ over the metal line M₁ as shown in FIG. 14. In FIG. 14, each via layer, including V₀, V₁, to Vₙ₋₂, Vₙ₋₁, may include one or more self-aligned vias 1001. The self-aligned vias 1001 has a larger linewidth than that of the via 1001A formed from traditional lithography or dual damascene process. Referring to FIGS. 5-12, the linewidths of the self-aligned vias 1001 depend on the pattern of the mask layer 402 that also determines the linewidth of the metal lines 1003 over the self-aligned vias 1001. In contrast, the linewidth of the via 1001A depends on the pattern of the PR layer 406.

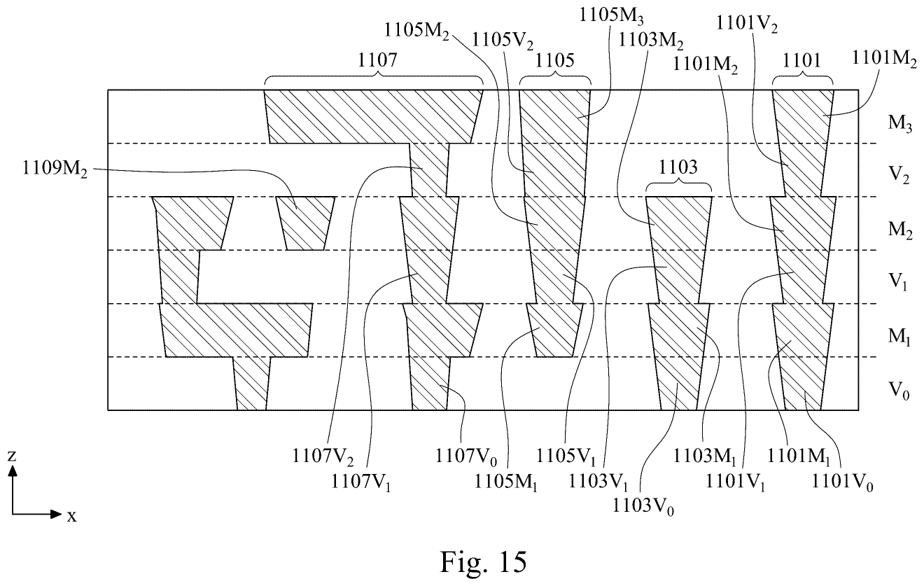

The self-aligned vias may be formed at any via layer V₀ to Vₙ as desired. FIG. 15 shows a BEOL interconnection structure that includes via layers V₀ to V₂ and metal-line layers M₁ to M₃ alternately stacked over each other. According to some embodiments, the BEOL interconnection structure may include a conductive feature 1101 extending vertically through all three metal-line layers M₁ to M₃ and all three via layers V₀ to V₂. The conductive feature 1101 includes the self-aligned vias 1101V₀, 1101V₁, and 1101V₂ formed at three consecutive via layers V₀, V₁, and V₂, respectively, and metal lines 1101M₁, 1101M₂, and 1101M₃ formed three consecutively metal-line layers M₁, M₂, and M₃, respectively. The metal lines 1101M₁, 1101M₂, and 1101M₃ are alternately stacked with the vias 1101V₀, 1101V₁, and 1101V₂. In some embodiments, a single self-aligned via may be formed at any of the via layers V₀, V₁, and V₂ without overlapping with any other self-aligned. The BEOL interconnection structure may also include a conductive feature 1103 that extends through only the metal-line layers M₁ and M₂, and via layers V₀ and V₁. The conductive feature 1103 includes the self-aligned vias 1103V₀ and 1103V₁ at the via layer V₀ and V₁, respectively, and metal lines 1103M₁ and 1103M₂ at the metal-line layers M₁ and M₂, respectively. The self-aligned vias 1103V₀, 1103V₁, and the metal lines 1103M₁ and 1103M₂ are alternately stacked with each other. Other conductive features, for example, the conductive feature 1107 may include a self-aligned via 1107V₁ at the via layer V₁ and vias 1107V₀ and 1107V₂ formed through traditional lithography process at the via layers V₀ and V₂, respectively. Some metal-line layer Mₙ, for example, metal-line layer M₂, may include a stand-alone metal line 1109M₂ that does not directly connect to any via formed in the adjacent via layers V₂ and V₁. The conductive feature 1105 includes metal line 1105M₃, 1105M₂, 1105M₁ in metal-line layers M₃, M₂, M₁, respectively and vias 1105V₁, 1105V₂ in vias layers V₁, V₂, respectively. According to some embodiments, the linewidth of the metal line 1105M₃ and the via 1105V₂ are larger than those of the metal line 1101M₃ and 1101V₂. The conductive feature does not include a via in the via layer V₀.

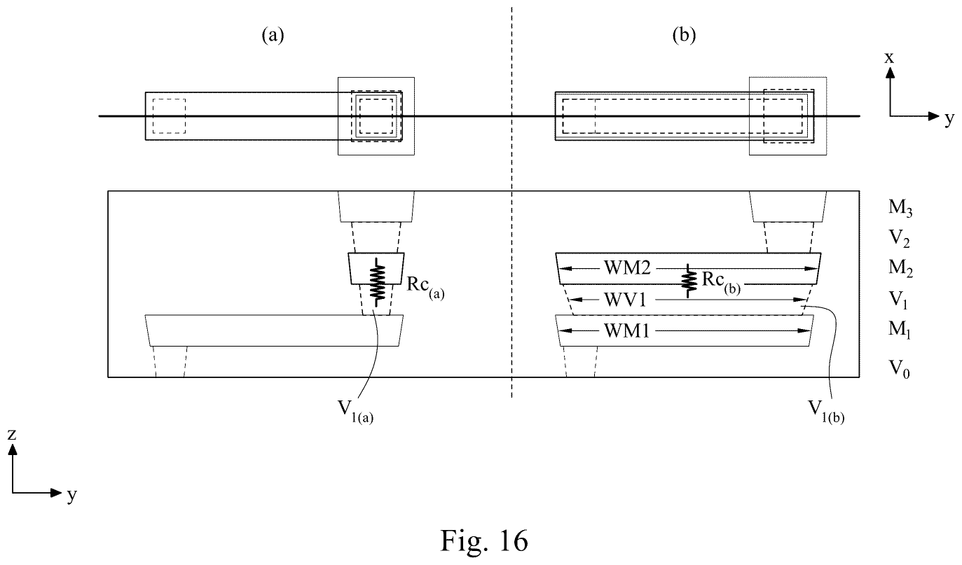

FIG. 16 shows a cross-section of a BEOL interconnection structure along the y-z plane and a cross-section of the BEOL interconnection structure along the x-z plane according to some embodiments. The BEOL interconnection structure includes vias layers V₀ to V₂ and metal-line layers M₁ to M₂ alternately stacked with each other. The BEOL interconnection structure includes a first region (a) in which V₁₍ₐ₎ may be made through traditional lithography and/or dual damascene process, while the via V_{1(b)} is a self-aligned via with an elongate side extending along y-axis. As shown in FIG. 15, the width of the metal lines in the metal line layers M₁, M₂, and the vial in the via layer V₁ are denoted as W_{M1}, W_{M2}, and W_{V1}, respectively. The ratio of W_{M1}/W_{V1} may range from about 0.5 to about 1, and the ratio of W_{M2}/M_{V1} may range from about 0.5 to about 1. The increased length of the via V_{1(b)} results in an increased surface area along the x-y plane across which current flows through. As a result, the contact resistance Rc_{(b)} (or sheet resistance Rs_{(b)}) is higher than the contact resistance Rc₍ₐ₎ (or sheet resistance Rs₍ₐ₎), which significantly reduces the RC delay.

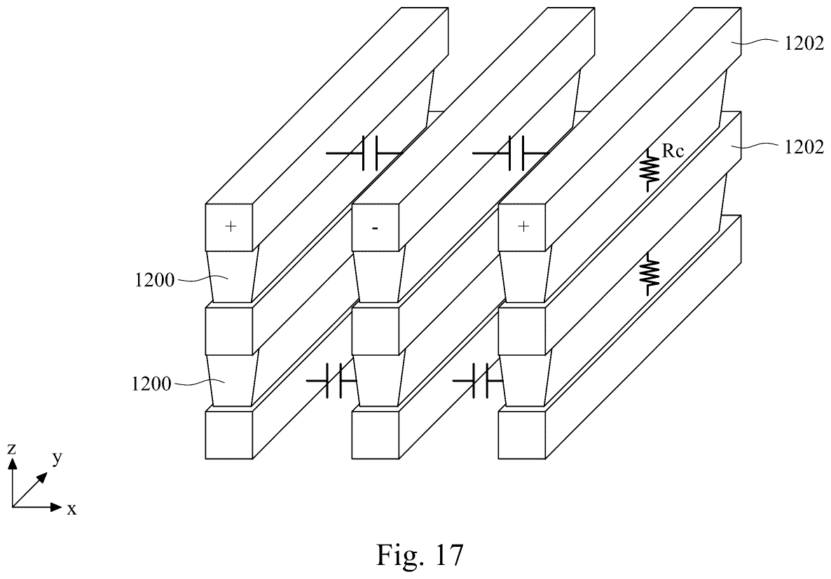

Metal-oxide-metal (MOM) capacitors are small and versatile devices used in integrated circuit (IC) chips. In the BEOL interconnection structure, via MOM (VIAMOM) may be constructed when currents of opposite conductive types flow through a pair of adjacent vias sandwiching a dielectric material in between. The VIAMOM structure may be applied to high-speed IC, microelectronics, RF and analog applications, and oscillator circuits. However, the traditional VIAMOM may suffer from issues such as low density, high resistance, and low breakdown voltage. According to some embodiments, the self-aligned via formation process may be applied for forming via metal-on-metal (VIAMOM) structure with higher capacitance. As shown in FIG. 17, a three-dimensional VIAMOM with line vias, that is, self-aligned via, may be formed by the operations as shown in FIGS. 5-12. In FIG. 17, each of the self-aligned vias 1202 has an elongate side extending along the y-axis. The contact resistance Rc or sheet resistance Rs for current flowing through the self-aligned via 1202 along the z-axis is reduced as the extended length along the y-axis significantly increases the contact surface area of the self-aligned via 1202. On the other hand, the capacitance of the VIAMOM, that is, the capacitor formed by two adjacent self-aligned line vias 414 and a dielectric layer formed in between along the x-axis is increased as the increased surface area may carry more chargers.

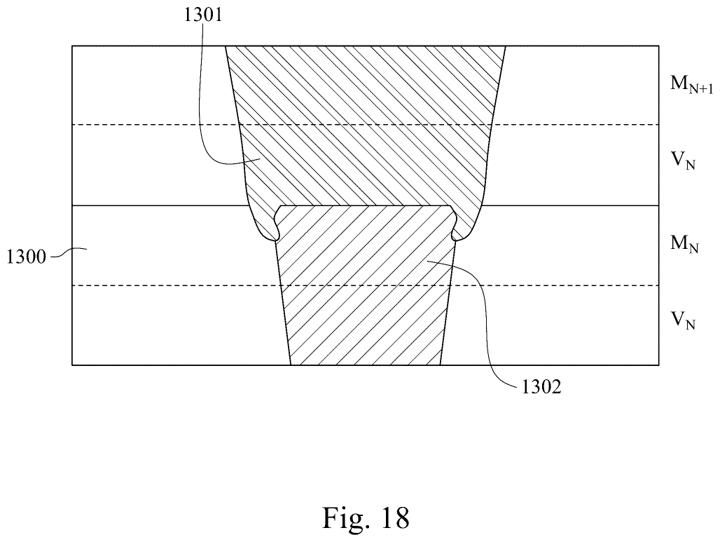

FIG. 18 shows another embodiment of a BEOL interconnection structure that includes a self-aligned via. The BEOL interconnection structure includes a stack of via layer V_{N}, a metal-line layer M_{N}, a via layer V_{N+1}, and a metal-line layer V_{N+1}. The linewidth of the self-aligned via 1301 at the via layer V_{N} is the same or larger than the linewidth of the underlying metal line 1302 at the metal line layer M_{N}. While forming the via opening by performing an etching process on the dielectric layer 1300, the portion of dielectric layer 1300 at the top corner regions of the metal line 1302 may be over etched to form a recessed notch. As a result, the self-aligned via 1301 formed over the metal line 1302 not only covers a top surface of the metal line 1302, but also wrap around a top portion of the sidewall thereof. The contact area between the self-aligned via 1302 and the metal line 1302 is thus increased to reduce the contact resistance Rc, and consequently shorten the RC delay.

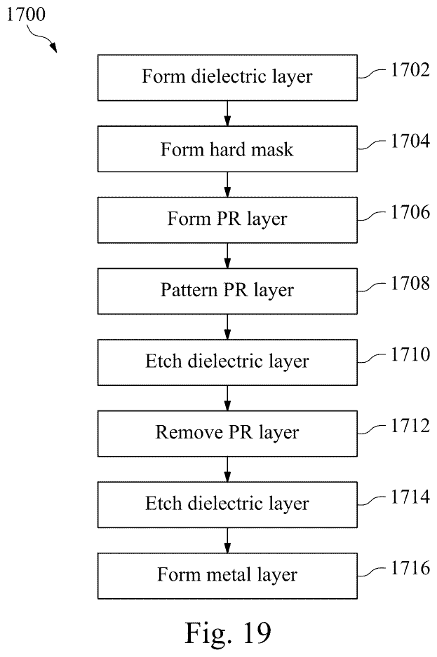

FIG. 19 shows a method of forming a BEOL interconnection structure with self-aligned via. The method includes operations for preparing various structures that may be referred to the structures as shown FIGS. 1-18. At operation 1700, a dielectric layer is formed on a device layer. The device layer may include various active and passive devices such as transistors, resistors, capacitors, diodes, imaging sensors, resistors, capacitors, inductors, memory cells, combinations thereof, and/or other suitable devices. In some embodiments, the transistors formed in the device layer may include nanostructure transistors having a plurality of channels wrapped around by the gate electrode layer. According to some embodiments, the device layer may include source/drain regions and conductive features connecting with the S/D regions as shown in FIGS. 1-3. The dielectric layer may be an inter-metal dielectric layer (IMD) or interlayer dielectric layer (ILD) having a low dielectric constant (k) value, for example, lower than about 2.0. The dielectric layer may include a single dielectric layer or multiple dielectric layers made of the same or different low-k dielectric materials with a thickness sufficient for forming both of a metal line and a via. The dielectric layer may be made of low-k dielectric materials such as a porous organosilicate thin film such as SiOCH, tetraethylorthosilicate (TEOS) oxide, un-doped silicate glass, doped silicon oxide such as borophosphosilicate glass (BPSG), fused silica glass (FSG), phosphosilicate glass (PSG), fluorine-doped silicon dioxide, carbon-doped silicon dioxide, porous silicon dioxide, porous carbon-doped silicon dioxide, silicon carbon nitride (SiCN), silicon oxycarbide (SiOCN), spin-on silicon based polymeric dielectrics, or combinations thereof. The dielectric layer may be formed through any of a variety of techniques, such as CVD, PVD, ALD, RPECVD, LSMCD, coating, spin-coating or another process that is adapted to form a thin film layer.

At operation 1704, a hard mask layer is formed on the dielectric layer. The hard mask layer may be patterned with openings to define metal lines. At operation 1406, a photoresist layer is formed over the dielectric layer. For example, referring to FIG. 5, openings 404 are formed to extend through the hard mask 402, and then filled by a photoresist (PR) layer 406 formed over the hard mask 406. The openings 404 expose the regions predetermined for forming metal lines that extend horizontally along the x-y plane to interconnect the conductive features formed in the adjacent metallization layers. For example, the trenches 404 formed in metallization layer Mₙ may be filled with metal layers subsequently to interconnect the conductive features formed in metallization layers Mₙ₋₁ and Mₙ₊₁. The mask layer 402 may be formed from silicon nitride through a process such as a CVD process, although other materials, such as oxides, oxynitrides, silicon carbide, combinations of these, or the like, and other processes, such as PECVD, LPCVD, or even silicon oxide formation followed by nitridation, may alternatively be utilized. A suitable photolithography process may then be performed to form the openings 404 that expose portions of the dielectric layer 400.

At operation 1706, a PR layer is formed over the hard mask layer and fill the openings in the hard mask layer. At operation 1708, the PR layer is patterned to expose some of the openings in the hard mask formed at operation 1704. According to some embodiments, a photolithography process may be performed on the PR layer to completely expose a predetermined number of the openings and partially exposes another one of the openings. The openings in the hard mask uncovered by the PR layer may be used to define self-aligned via openings. That is, the self-aligned via openings may be defined with the same hard mask used for defining trench in which the metal line is to be formed. In contrast, as via openings defined by the partially exposed openings require assistance of the PR layer, via may be formed within such via opening through traditional damascene process. In addition, some of the openings in the hard mask may be completely covered by the PR layer to define the metal line that extends horizontally in the same metal line layer.

At operation 1710, the exposed portions of the dielectric layer are removed with a predetermined depth. The PR layer is then removed to expose the openings 404 that are previously covered or partially covered at operation 1712. The exposed dielectric layer is further etched to form trenches at operation 1714. The etching process is performed until the via openings, including the via defined by the PR layer and the self-aligned vias defined by the hard mask layer extend through the dielectric layer to expose the device layer underlying the dielectric layer.

At operation 1716, a metal layer is formed over the hard mask 412 and fills the openings, including the openings in the hard mask, the trenches formed at operation 1712, and the via openings. Before the metal layer is formed, a barrier layer (not shown) may be conformally formed. The barrier layer may be deposited by CVD or PVD. The barrier layer may be used to prevent the metal layer from diffusing into the dielectric layer. The barrier layer may also improve the adhesion to the metal layer. The barrier layer may be made of a substantially aluminum free material such as Ta, TaN, TiN, or a composite layer made of Ta and TaN. In some embodiments, a thin seed layer is optionally formed on the barrier layer. The see layer may include a metal alloy layer containing at least a main metal element, for example, copper (Cu) and an additive element such as manganese (Mn). In other embodiments, Ti, Nb, Cr, V, Y, Tc, Re, or other suitable material may be used as an additional for forming the seeding layer. The seeding layer may be formed by PVD, CVD, PECVD, LPCVD, or other deposition techniques.

The material for forming the metal layer may include Cu or Cu alloys. Other materials such as silver, gold, tungsten, and the like may also be used for forming the metal layer. The metal layer may be formed from an electrochemical copper deposition (ECD) process. The ECD process is adopted because of its high deposition and may result in larger grain size to ensure good electromigration. After formation of the metal layer, thermal treatment such as an annealing process is performed. A chemical mechanical polishing (CMP) process is then performed until the hard mask layer is removed.

The method 1700 allows self-aligned vias with larger surface areas to be formed while metal lines and vias made through traditional dual damascene process are formed. The increased surface areas of the self-aligned vias not only reduces the contact resistance and improves RC delay, but can also be applied to form VIAMOM with higher capacitance.

According to one embodiment, an interconnection structure over a device layer is provided. The interconnection structure comprises a first metal line in a dielectric layer and a first via self-aligned with the first metal line along a z-axis in the dielectric layer. The first via has a width W along an x-axis and a length L along a y-axis, where W/L ranges from about 1:3 to about 1:80.

According to another embodiment, an interconnection structure over a device layer is provided. The interconnection structure comprises a plurality of metal-line layers and a plurality of via layers. The metal-line layers and the via layers are alternately stacked with each other along a first direction. The interconnection structure further comprises a first conductive feature extending through at least one of the metal-line layers and at least one of the via layers immediately adjacent to the at least one metal-line layer. The conductive feature comprises a first metal line in the at least one metal-line layer and a first via in the at least one via layer. The first via is self-aligned under the first metal line and has an elongate side extending along a second direction perpendicular to the first direction.

According to yet another embodiment, a method is provided. A dielectric layer is formed. A hard mask layer is formed on the dielectric layer. The hard mask layer has a plurality of openings exposing portions of the dielectric layer. A patterned photoresist layer on the hard mask layer to cover a first number of the openings, partially expose a second number of the openings, and uncover a third number of the openings. The dielectric layer partially exposed and uncovered by the photoresist layer are removed with a predetermined depth. The photoresist layer is removed. The dielectric layer exposed by the hard mask layer is etched until the second number and the third number of the openings extending through the dielectric layer. The first, second, and third number of openings is filled with conductive material to forming metal lines, dual damascene vias, and self-aligned vias.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An interconnection structure over a device layer, comprising:
a plurality of metal-line layers;
a plurality of via layers, the plurality of metal-line layers and the plurality of via layers being alternately stacked with each other along a first direction;
a first conductive feature extending through at least one of the metal-line layers and at least one of the via layers immediately adjacent to the at least one of the metal-line layers, wherein
the first conductive feature comprises a first metal line in the at least one metal-line layer and a first via in the at least one via layer, the first via being self-aligned under the first metal line and has an elongate side extending along a second direction orthogonal to the first direction.

2. The interconnection structure of claim 1, wherein each of the metal-line layers comprises a plurality of metal lines formed in a dielectric layer, and each of the via layers comprises a plurality of vias formed in the dielectric layer.

3. The interconnection structure of claim 1, wherein the first via has a linewidth along a third direction orthogonal to both the first and second directions, and a ratio of a width W_{M1} of the first meta line to a width W_{V1} of the first via along the second direction is about 0.5 to about 1.

4. The interconnection structure of claim 1, further comprising a second conductive feature, the second conductive feature comprising:
a second metal line in the at least one metal-line layer; and
a second via in the at least one via layer and directly connected with the second metal line, wherein the second via has a linewidth smaller than a linewidth of the first via.

5. The interconnection structure of claim 1, wherein the first metal line and the first via form a substantially continuous sidewall profile.

6. The interconnection structure of claim 1, further comprising:
a second conductive feature comprising a second metal line in the at least one metal-line layer; and
a second via in the at least one via layer and directly connected with the second metal line, wherein
the second via and the second metal line form a discontinuous sidewall profile.

7. The interconnection structure of claim 1, wherein elongate side of the self-aligned via extends across over more than one active region formed in the device layer.

8. The interconnection structure of claim 1, further comprising a stand-alone third conductive feature comprising a stand-alone metal line in the at least one metal-line layer without direct connection with any via formed in the via lines.

9. An interconnection structure over a device layer, comprising:
a first metal line in a dielectric layer; and
a first via self-aligned with the first metal line along a z-axis in the dielectric layer, wherein
the first via has a first linewidth W along an x-axis and a length L along a y-axis, where W/L ranges from about 1:3 to about 1:80.

10. The interconnection structure of claim 9, further comprising a second via and a second metal line in the dielectric layer, wherein the second via has a second linewidth along the x-axis, the second linewidth is smaller than the first linewidth of the first via, and the second metal line is formed over and in direct contact with the second via.

11. The interconnection structure of claim 10, wherein the second metal line and the second via form a discontinued sidewall profile.

12. The interconnection structure of claim 11, wherein the discontinued sidewall profile has a step with a width of about 0.2 μm at a boundary of the second metal line and the second via.

13. The interconnection structure of claim 9, wherein the first metal line and the first via self-aligned under the first metal line form a substantially continuous sidewall profile.

14. The interconnection structure of claim 9, further comprising a stand-alone metal line without direct connection with any via in the dielectric layer.

15. The interconnection structure of claim 9, wherein the dielectric layer includes a single layer of low-k dielectric material.

16. The interconnection structure of claim 9, wherein the dielectric layer includes multiple layers made of the same or different dielectric materials.

17. The interconnection structure of claim 9, further comprising:
a third metal line in the dielectric layer;
a third via self-aligned under the third metal line along the z-axis, the third via being stacked over the first metal line and having a contact surface extending over a top surface and a top portion of a sidewall of the first metal line.

18. The interconnection structure of claim 9, further comprising a via metal-oxide-metal structure (VIAMOM), the VIAMOM comprising:
the first via;
a fourth via formed in parallel with the first via; and
the dielectric layer between the first via and the third via, wherein the third via having a W/L ratio ranging from about 1:3 to about 1:80.

19. A method, comprising:
forming a dielectric layer;
forming a hard mask layer on the dielectric layer, the hard mask layer having a plurality of openings exposing portions of the dielectric layer;
forming a patterned photoresist layer on the hard mask layer to cover a first number of the openings, partially expose a second number of the openings, and uncover a third number of the openings;
removing the dielectric layer partially exposed and uncovered by the photoresist layer with a predetermined depth;
removing the photoresist layer; and
etching the dielectric layer exposed by the hard mask layer until the second number and the third number of the openings extending through the dielectric layer; and
filling the first, second, and third number of openings with conductive material to form metal lines, dual damascene vias, and self-aligned vias.

20. The method of claim 19, wherein the self-aligned vias has a width (W) to length (L) ratio (W/L) smaller than a W/L of the dual damascene vias.
